(19) United States
(12) Patent Application Publication
(10) Pub. No.: US 2022/0319556 A1
(43) Pub. Date: Oct. 6, 2022

(54) RAPID POWER REDUCTION FOR NON-VOLATILE MEMORY EXPRESS STORAGE

(71) Applicant: Dell Products L.P., Round Rock, TX (US)

(72) Inventors: Wei DONG, Shanghai (CN); Haifang ZHAI, Shanghai (CN); Wei SHU, Shanghai (CN); Xu CHEN, Shanghai (CN)

(73) Assignee: Dell Products L.P., Round Rock, TX (US)

(21) Appl. No.: 17/244,215

(22) Filed: Apr. 29, 2021

(30) Foreign Application Priority Data
Apr. 1, 2021 (CN) 202110358088.4

(51) Int. Cl. G11C 5/14; G06F 1/24; G06F 11/30

(52) U.S. Cl. CPC G11C 5/14; G06F 1/24; G06F 11/3037

(57) ABSTRACT

A disclosed power management method includes monitoring a particular connector pin of a storage device and responsive to detecting a predetermined signal on the particular pin, performing rapid throttle operations including throttling the storage device to a low power consumption mode. The storage device might be an NVMe device and the particular connector pin may be a dual port enable pin of a U.2 connector or an EDSFF connector. Following a cold or warm reset, the particular connector pin may be monitored for an indication of whether a dual port enablement feature is provided. When the predetermined signal is not detected on the particular pin, an operating system may be permitted to upwardly adjust power levels for the power supply unit. In at least one embodiment, the predetermined signal may be a square wave signal generated by a field programmable gate array.

### TECHNICAL FIELD

The present disclosure relates to storage devices for information handling systems and, more specifically, thermal management for non-volatile storage devices.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

During operation, information handling system components generate heat that must be dissipated as efficiently as possible. Historically, because processing components, including central processing units (CPUs) and graphics processing units (GPUs), generate more heat than other components, much of the heat sink design and other thermal management considerations have focused on the processing components. More recently, however, the power density of storage drives has increased significantly. For example, whereas a typical 2.5″ SAS hard disk drive (HDD) consumed 9 W and a typical 2.5″ SAS solid state drive (SSD) consumed 14 W, a 2.5″ U.2 non-volatile memory express (NVMe) drive consumes 25 W and an enterprise and data center SSD form factor (EDSFF) NVMe device may consume anywhere from 20 W to 70 W. The higher thermal design point (TDP) of NVMe drives has created a thermal management challenge that has generally resulted in increased power for cooling components and systems. In addition, because NVMe drives are high performing, these drives are typically coupled with high performing CPUs, which results in still additional thermal loading. As a result, the thermal management platform for information handlings systems employing large scale NVMe storage may have a narrow margin of error such that the power supply unit (PSU) may be unable to support full performance if any of the thermal management components fail.

### SUMMARY

In accordance with teachings disclosed herein, common problems associated with conventional power throttling are addressed, in whole or part, by a power management method, which includes monitoring a particular connector pin of a storage device and, responsive to detecting a predetermined signal on the particular pin, performing rapid throttle operations including throttling the storage device to a low power consumption mode. The storage device might be an NVMe device or another SSD device and the particular connector pin may be a dual port enable (DualPortEn#) pin of a connector selected from: a U.2 connector and an EDSFF connector. Monitoring the particular connector pin may include monitoring, following a cold or warm reset, the particular connector for a dual port enablement indication. The rapid throttle operations may further include increasing NAND flash bus traffic delay. When the predetermined signal is not detected on the particular pin, an operating system may be permitted to upwardly adjust power levels for the power supply unit. In at least one embodiment, the predetermined signal comprises a square wave signal generated by a field programmable gate array. The gate array may generate the particular signal upon receiving a throttle power signal from a power supply unit.

In further accordance with disclosed teachings, an information handling system may include a central processing unit (CPU), a baseboard management controller (BMC), a PSU configured to send a PSU_throttle signal responsive to a power level of the PSU exceeding a threshold. The system may further include a field programmable gate array (FPGA) configured to generate a particular signal responsive to receiving the PSU_throttle signal and to forward the particular signal to a particular pin of an NVMe device. The NVMe device may include a storage controller configured to recognize the predetermined signal as a highest priority interrupt that triggers PSU throttling.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an information handling system in accordance with disclosed fast power throttling features;

FIG. 2 illustrates elements of the information handling system of FIG. 1 employed in a rapid power throttling method; and

FIG. 3 illustrates a flow diagram of a power management method in accordance with disclosed subject matter.

### DETAILED DESCRIPTION

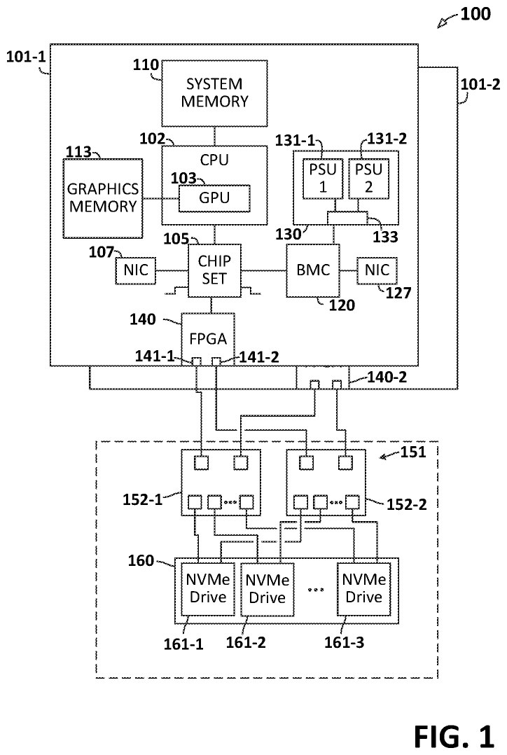

Exemplary embodiments and their advantages are best understood by reference to FIGS. 1-3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

Additionally, an information handling system may include firmware for controlling and/or communicating with, for example, hard drives, network circuitry, memory devices, I/O devices, and other peripheral devices. For example, the hypervisor and/or other components may comprise firmware. As used in this disclosure, firmware includes software embedded in an information handling system component used to perform predefined tasks. Firmware is commonly stored in non-volatile memory, or memory that does not lose stored data upon the loss of power. In certain embodiments, firmware associated with an information handling system component is stored in non-volatile memory that is accessible to one or more information handling system components. In the same or alternative embodiments, firmware associated with an information handling system component is stored in non-volatile memory that is dedicated to and comprises part of that component.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

In the following description, details are set forth by way of example to facilitate discussion of the disclosed subject matter. It should be apparent to a person of ordinary skill in the field, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically. Thus, for example, device “12-1” refers to an instance of a device class, which may be referred to collectively as devices “12” and any one of which may be referred to generically as a device “12”.

Referring now to the drawings, FIG. 1 illustrates a block diagram of selected elements of an information handling system 100 in accordance with rapid power throttling features disclosed herein. The information handling system 100 illustrated in FIG. 1 includes a pair of host systems referred to herein as first host 101-1 and second host 101-2, communicatively coupled to a storage subsystem 150 that includes a storage array 160 including two or more NVMe drives 161.

Each host 101 illustrated in FIG. 1 includes one or more central processing units 102, only one of which is illustrated in FIG. 1, communicatively coupled to a system memory 110 and a chipset 105. The illustrated CPU 102 includes an integrated graphic processing unit (GPU) 103, which is coupled to a graphics memory 113. In other embodiments (not depicted), CPU 102 may omit an integrated GPU and, in such embodiments, a separate GPU may be included. Chipset 105 provides, supports, and/or manages various busses, interconnects, transports, etc., coupling various peripheral devices with CPU 102 and other system resources. For the sake of clarity and brevity, the only peripheral resources shown coupled to chipset 105 in FIG. 1 include a network interface (NIC) 107, a baseboard management controller 120, and a field programmable gate array (FPGA) 140. Those of ordinary skill in the field of information handling system design will, however, recognize that numerous other peripheral devices may be coupled to chipset 105 without departing from the scope of the subject matter disclosed herein.

Each host 101 illustrated in FIG. 1 includes a power supply module 130 featuring two power supply units (PSUs) (131-1 and 131-2). In at least one embodiment, PSUs 131-1 and 131-2 are configured to provide 1+1 redundancy wherein one of the PSUs 131 is designated as the primary PSU while the other PSU serves as the redundant PSU. While the primary PSU is functional, it provides substantially all power to the host's resources including, in at least some embodiments, storage subsystem 150. In the event of a primary PSU failure, the redundant PSU powers the system and maintains the system's availability. In at least some embodiments, the two PSUs are functionally equivalent or substantially equivalent and either PSU 131-1 or 131-2 can function as either the primary PSU or the redundant PSU. In other embodiments (not depicted), power supply module 130 may include more or fewer PSUs 131 and not include any redundancy.

BMC 120 is a resource for managing host 101. In at least some embodiments, BMC 120 is remotely accessible via NIC 127, which may be coupled to a management network (not depicted). In some embodiments, BMC 120 may include features and functionality analogous to features and functionality found in the integrated Dell remote access controller (iDRAC) 9 or later versions from Dell, Inc. The BMC 120 illustrated in FIG. 1 is coupled to chipset 105, a network interface card (NIC) 127, and power supply module 130 via power connector 133.

The storage subsystem 150 illustrated in FIG. 1 includes a transport fabric 151 providing multiple paths between hosts 101 and the NVMe drives 161 in storage array 160. Transport fabric 151 may include PCIe switches, storage controllers, or both, which may be implemented in a variety of specific configurations and it should be readily apparent that the illustrated configuration of transport fabric 151 is a non-limiting example. The transport fabric 151 illustrated in FIG. 1 supports dual-ported configurations in which each NVMe 161 can be connected to either or both hosts 101. Each host illustrated in FIG. 1 includes an FPGA 140 to provide hardware acceleration for I/O transactions between hosts 101 and, in dual port platforms, each FPGA 140 is configured with first and second ports 141-1 and 141-2. The port pairs 141-1 and 141-2 of the two hosts 101-1 and 101-2 are cross-coupled with PCIe switches 152 such that a distinct path exists between each host 101 and each PCIe switch 152. Similarly, on the NVMe “side” of transport fabric 151, each NVMe drive 161 is coupled to at least one port in the first PCIe switch 152-1 and at least one port in second PCIe switch 152-2. port in the illustrated embodiment includes a separate path to each of the PCIe switches 152.

Those of ordinary skill will recognize that the storage subsystem 150 illustrated in FIG. 1 consumes considerable power and generates significant heat. NVMe drives such as the NVMe drives 161 in FIG. 1 generally have a TDP that is significantly higher than the TDP of serial attached SCSI (SAS) HDDs and SSDS. To dissipate heat generated by NVMe drives, additional power is required for fans, pumps, and other cooling elements. In addition, NVMe drives offer higher performance than comparable SAS drives and are generally coupled with higher performing CPUs and I/O devices, resulting in still more power consumption. The platform illustrated in FIG. 1 and comparable platform configurations employing multiple NVMe drives require more power budget than storage subsystems have generally been allotted. To illustrate with some examples, a system employing a flash array with 48 2.5″ U.2 form factor NVMe drives configured via NVMe over fabrics (NVMeOF) may result in total power consumption between 1800-2000 W including 1200 W for the drives, 300-400 W for cooling fan and another 300-400 W for the fabric and PCIe switches. Recognizing that, a PSU larger than 2000 W may requires a larger and more expensive power connector such as a C19 or C20 connector, it would be highly beneficial to configure this platform to operate with a single 1800 W PSU and rapid power throttling may be one component for achieving that objective. A technique for rapidly throttling storage power consumption would also be beneficial for some exemplary, lower power platforms. As an example, a platform employing 25 2.5″ U.2 NVMe drives, each with a 25 W TDP, in an NVMeOF configuration could approach or exceed 1200 W, in which case the platform would be unable to use low line input because low line power supplies cannot exceed 1200 W. To operate well below the 1200 W limit, it may again be beneficial to invoke rapid throttling under prescribed conditions.

Conventional power throttling approaches including, as examples, CPU down core mode or down frequency mode, typically require a storage controller reset/restart and it would be beneficial to implement a power throttling technique that did not require a reset

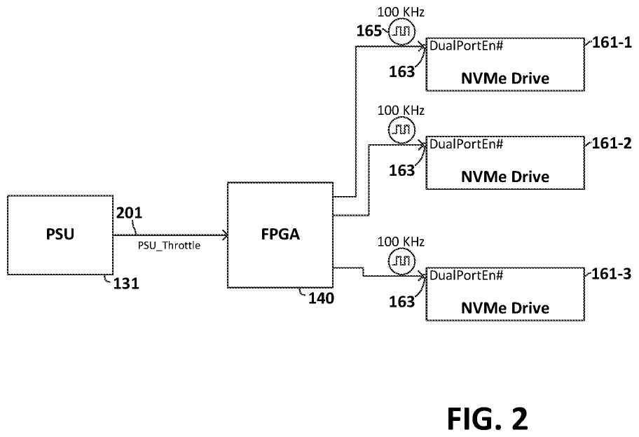

Turning now to FIG. 2, selected elements of information handling system 100 (FIG. 1) employed during a rapid power throttling feature are illustrated. FIG. 2 illustrates a PSU 131 sending a PSU throttle signal 201 to FPGA 131. PSU 131 may have been triggered to assert PSU throttle signal 201 based on the power consumption exceeding a threshold value or based on detecting one or more other criteria. The FPGA 140 is configured to generate a predetermined signal 165 in response to detecting the PSU Throttle signal 201. In at least one embodiment, the predetermined signal may be a square wave with a specific frequency and duty cycle. As an example, the predetermined signal may be a 100 KHz square wave signal with a 50% duty cycle. The predetermined signal 165 is illustrated in FIG. 2 as being sent to a particular pin of the applicable NVMe drive 161. The particular pin 163 is preferably a pin that would not normally be used as an input or output during conventional operation. The particular pin 163 illustrated in FIG. 2 is the dual port enable (DualPortEn#), which is a pin on a U.2 or EDSFF connector. The DualPortEn# pin may be advantageously employed to initiate rapid throttling because the pin's normal function, i.e., enabling dual port configuration, is typically only performed following a cold or warm reset, at which point it is unlikely that the storage subsystem may be drawing sufficient power to invoke power throttling. Each NVMe drive 161 may be configured to treat the predetermined signal 165 as a highest priority interrupt and each NVMe drive 161 may include an interrupt handler configured to throttle power in response to the interrupt. The throttling may include throttling PSU power level to 50% or less of its pre-throttled value. For a 25 W 2.5″ U.2 SSD, as an example, throttling may include throttling the PSU power level to 10 W.

As described in more detail below, the particular pin of the NVMe drive may have a second function apart from triggering power level throttling. In the case of DualPortEn#, the second function may be to indicate whether dual port functionality is enabled. More specifically, if the information handling system 100 supports dual port functionality, the DualPortEn# pin may be used to convey whether the dual port functionality is enabled. Advantageously, both functions can be conveyed via the same pin because the dual port functionality is only enabled or disabled following a cold or warm reset, during which time, power throttling is not going to occur. Conversely, power throttling is only likely to occur well after a cold or warm reset has taken place.

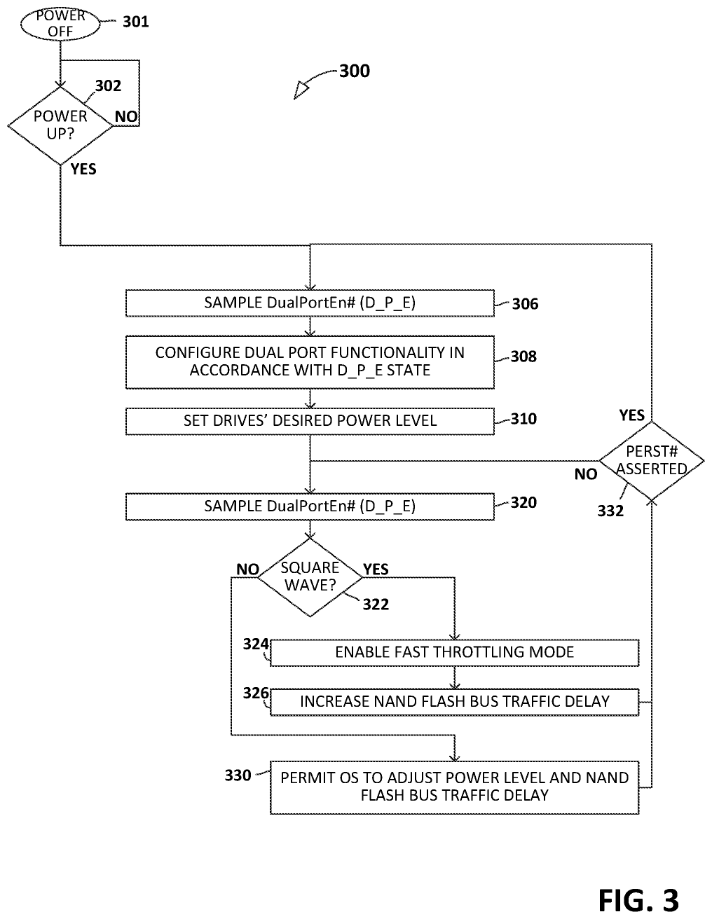

Referring now to FIG. 3, a flow diagram illustrates a method 300 of implementing rapid power throttling. The illustrated embodiment of method 300 begins with the system in a power off state 301. The system transitions out of the power off state 301 in response to a power up event 302. In its conventional function, the Dual Port Enable pin is sampled (block 306), either shortly after power is applied (PCIe cold reset) or shortly after a PERST# signal is asserted (block 332) with power already applied (PCIe warm reset), to enable or disable (block 308) dual port functionality and to set (block 310) the desired power level for the NVMe drives. Thus, in the absence of a system reset or power off/on sequence, the Dual Port Enable pin is essentially unused.

Following the setting of the desired power level(block 310), the illustrated embodiment of method 300 enters a loop, in which DualPortEn# is sampled (block 320). If a predetermined signal, such as a 100 KHz square wave signal, is detected (block 322) on the DualPortEn# pin, rapid power throttling is enabled (block 324) and, to further reduce power consumption, NAND flash bus traffic delay may be increased (block 326). If the predetermined signal is not detected when DualPortEn# is sampled (block 320), rapid power throttling is not indicated and the storage subsystem may permit (block 330) the operating system (OS) to adjust power levels upward if more power is called for and power budget is available.

Following either of the operations 326 or 330, the illustrated method 300 determines (block 332) whether PERST# is asserted. If PERST# is asserted, a warm reset has occurred and the method 300 branches back to the initialization steps 306 through 310 discussed above. If, however, PERST# is not asserted, method 300 branches to block 320, where DualPortEn# is again sampled for the presence of a square wave or another predetermined signal.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A power management method, comprising:
monitoring a particular connector pin of a storage device;
responsive to detecting a predetermined signal on the particular pin, performing rapid throttle operations including:
throttling the storage device to a low power consumption mode.

2. The power management method of claim 1, wherein the storage device comprises a solid state drive.

3. The power management method of claim 1, wherein the solid state drive comprises a non-volatile memory express drive.

4. The power management method of claim 3, wherein the particular connector pin comprises a dual port enable (DualPortEn#) pin of a connector selected from: a U.2 connector and an Enterprise and Data Center SSD form factor (EDSFF) connector.

5. The power management method of claim 4, wherein monitoring the particular connector pin comprises monitoring, following a cold or warm reset, the particular connector for a dual port enablement indication.

6. The power management method of claim 1, wherein the rapid throttle operations include increasing NAND flash bus traffic delay.

7. The power management method of claim 1, further comprising:
responsive to not detecting the predetermined signal on the particular pin, permitting an operating system to upwardly adjust power levels.

8. The power management method of claim 1, wherein the predetermined signal comprises a square wave signal generated by a field programmable gate array.

9. The power management method of claim 8, wherein the square wave signal has a frequency of 100 KHZ.

10. An information handling system, comprising:
a central processing unit (CPU);
a baseboard management controller;
a power supply unit (PSU) configured to send a PSU_throttle signal responsive to a power level of the PSU exceeding a particular threshold;
a field programmable gate array FPGA configured to generate a particular signal responsive to receiving the PSU_throttle signal and to forward the particular signal to a particular pin of the an NVMe drive;
wherein the NVMe drive is configured to receive the particular signal on the particular and to respond by throttling to a low power consumption state.

11. The information handling system of claim 10, wherein the particular signal comprises a square wave signal.

12. The information handling system of claim 11, wherein a frequency of the square wave signal is 100 KHz.

13. The information handling system of claim 10, wherein the NVMe drive is configured to recognize the particular signal as a priority interrupt signal.

14. The information handling system of claim 10, wherein the particular pin comprises a DualPortEn# signal.

15. The information handling system of claim 10, wherein the NVMe drive is configured to detect a dual port enablement signal at the particular pin following a cold or warm reset.
